(19) United States
(12) Patent Application Publication
(10) Pub. No.: US 2006/0183266 A1
(43) Pub. Date: Aug. 17, 2006

(54) Method of fabricating CMOS image sensor

(76) Inventor: Chang Hun Han, Icheon city (KR)

Correspondence Address: MCKENNA LONG & ALDRIDGE LLP;Song K. Jung, 1900 K Street, N.W., Washington, DC, 20006, US

(21) Appl. No.: 11/320,739

(22) Filed: Dec. 30, 2005

(30) Foreign Application Priority Data
Feb. 17, 2005 (KR) P 2005-0013155

(51) Int. Cl. H01L 21/00

(52) U.S. Cl. 438/70

(57) ABSTRACT

A method of fabricating an image sensor includes the steps of sequentially stacking a metal layer and a nitride layer over a semiconductor substrate divided into an active area and a pad area; forming a metal pad on the pad area by selectively patterning the nitride layer and the metal layer; forming a protecting layer over the semiconductor substrate including the metal pad, forming a pad opening over the metal pad by selectively removing the protecting layer until a surface of the nitride layer is exposed; forming a color filter layer over the active area of the semiconductor substrate; forming a microlens over the color filter layer; and selectively removing the nitride layer exposed via the pad opening.

### CROSS-REFERENCE TO RELATED APPLICATION

This application claims the benefit of Korean Patent Application No. 10-2005-0013155, filed on Feb. 17, 2005, which is hereby incorporated by reference as if fully set forth herein.

### BACKGROUND OF THE INVENTION

1. Field of the Invention

The present invention relates to a CMOS image sensor, and more particularly, to a method of fabricating a CMOS image sensor. Although the present invention is suitable for a wide scope of applications, it is particularly suitable for enhancing characteristics and output of the image sensor.

2. Discussion of the Related Art

Generally, an image sensor is a semiconductor device that converts an optical image to an electric signal. Image sensors are primarily classified as a charge coupled device (CCD) or a complementary metal oxide silicon (CMOS) image sensor.

The CCD has a complicated drive system, requires considerable power consumption, and requires a multi-step photo process. As such, the process of fabricating a CCD is complicated. Moreover, the CCD has difficulty integrating a control circuit, a signal processing circuit, an analog/digital (A/D) converter and other components on a CCD chip. As such, it is difficult to reduce the size of a CCD. A CMOS image sensory attempts to overcome the disadvantages of the CCD.

In the CMOS image sensor, MOS transistors corresponding to the number of unit pixels are formed on a semiconductor substrate by CMOS technology using a control circuit, a signal processing circuit and other components as peripheral circuits. Hence, the CMOS image sensor adopts a switching system that sequentially detects outputs of the unit pixels via the MOS transistors.

Using CMOS fabrication technology, the CMOS image sensor advantageously has low power consumption and a simple fabricating process due to a small number of photo processing steps. Since a control circuit, a signal processing circuit, an analog/digital (A/D) converter and other components can be integrated on a CMOS image sensor, chip, a smaller sized CMOS image sensor is facilitated.

The CMOS image sensors are widely used in various application fields, such as a digital photo cameras and digital video cameras.

A conventional CMOS image sensor is explained in detail with reference to FIG. 1 and FIG. 2. FIG. 1 is a diagram of an equivalent circuit of a unit pixel of a 3T type CMOS image sensor having three transistors, and FIG. 2 is a layout of the unit pixel of the CMOS image sensor shown in FIG. 1.

Referring to FIG. 1, a unit pixel of a typical 3T type CMOS image sensor has one photodiode PD and three NMOS transistors T1 to T3. A cathode of the photodiode PD is connected to a drain of the first NMOS transistor T1 and a gate of the second NMOS transistor T2.

Sources of the first and second NMOS transistors T1 and T2 are connected to a power line supplying a reference voltage VR, and a gate of the first NMOS transistor T1 is connected to a reset line supplying a reset signal RST.

A drain of the third NMOS transistor T3 is connected to a drain of the second NMOS transistor T2. A source of the third NMOS transistor T3 is connected to a read circuit (not shown) via a signal line. A gate of the third NMOS transistor T3 is connected to a row select line supplying a select signal SLCT.

The first to third NMOS transistors T1 to T3 are designated a reset transistor Rx, a drive transistor Dx and a select transistor Sx, respectively.

Referring to FIG. 2, an active area 10 is defined in a unit pixel of the typical 3T type CMOS image sensor. One photodiode 20 is formed on a wide region of the active area 10 and three gate electrodes 120, 130 and 140 are overlapped with the rest of the active area 10.

The gate electrode 120 configures a reset transistor Dx. The gate electrode 130 configures a drive transistor Dx. The gate electrode 140 configures a select transistor Sx.

The active area 10 of each of the transistors, except the portion overlapped with the corresponding transistor, is doped with impurity ions to become source/drain regions of each of the transistors.

A power voltage Vdd is applied to the source/drain regions between the reset and drive transistors Rx and Dx, and the source/drain region of the select transistor Sx is connected to a read circuit (not shown).

Moreover, the gate electrodes are connected to signal lines (not shown), respectively. A pad is provided to each of the signal lines to connect to an external drive circuit.

A process of forming the pad and other components in the CMOS image sensor is explained in detail with reference to FIGS. 3A to 3E.

Referring to FIG. 3A, an insulating layer 101 (e.g., an oxide layer), such as a gate insulating layer, an insulating interlayer and/or other layers, is formed on a semiconductor substrate 100. A metal pad 102 of each signal line is formed on the insulating layer 101.

The metal pad 102 can be formed on the same layer of the gate electrodes 120, 130 and 140, as described in FIG. 2, with the same material of the gate electrodes 120, 130 and 140. Alternatively, the metal pad 102 can be formed of a material different from that of the gate electrodes 120, 130 and 140 via a separate contact.

To raise the corrosion-resistance of the metal pad 102 formed of Al, a surface treatment is carried out on a surface of the metal pad 102 using UV-ozone or synthesized solution.

Subsequently, a protecting layer 103 is formed on the insulating layer 101 including the metal pad 102. The protecting layer 103 can be formed by an oxide layer, a nitride layer or other materials.

Referring to FIG. 3B, a photoresist 104 is coated on the protecting layer 103. The photoresist 104 is patterned by exposure and development to expose a portion of the protecting layer 103 over the metal pad 102.

The exposed portion of the protecting layer 103 is selectively etched using the patterned photoresist 104 as an etch mask to form a pad opening 105 on the metal pad 102.

Referring to FIG. 3C, the patterned photoresist is removed. A first planarizing layer 106 is formed by depositing a silicon nitride layer or a silicon oxide nitride layer over the semiconductor substrate 100, including the pad opening 105. The first planarizing layer 106 is selectively etched by photolithography to remain only on the active area.

Color filter layers 107 are formed on the first planarizing layer 106 corresponding to photodiode areas (not shown), respectively. Each of the color filter layers is formed by coating a corresponding color resist and by performing a photo process using a separate mask.

Referring to FIG. 3D, a second planarizing layer 108 is formed over the semiconductor substrate 100, including the color filter layers 107. The second planarizing layer 108 is selectively etched by photolithography to remain only on the active area.

Referring to FIG. 3E, a hemispherical microlens 109 is formed on the second planarizing layer 108 to correspond to each of the color filter layers 107.

After a contact resistance is tested by performing a probe test on the metal pad 102 of the above-fabricated CMOS image sensor, the metal pad is electrically connected to an external drive circuit.

However, in the conventional CMOS image sensor, the first planarizing layer, the color filter layers, the second planarizing layer and the microlenses are sequentially formed after completion of the pad opening on the metal pad. Each process is carried out while the metal pad is exposed. The metal pad reacts with a TMAH-based alkali developing solution to form oxide layer having a considerable thickness. Hence, the physically vulnerable metal pad may be stripped by a physical force applied in performing the probe test.

Since metal particles of the metal pad are deposited on a light-receiving area and reflect light, performance and output of the CMOS image sensor are reduced.

### SUMMARY OF THE INVENTION

Accordingly, the present invention is directed to a method of fabricating a CMOS image sensor that substantially obviates one or more problems that may be due to limitations and disadvantages of the related art.

The present invention provides a method of fabricating a CMOS image sensor, by which characteristics and output of the image sensor are enhanced by preventing a metal pad from contacting with an alkali developing solution.

Additional advantages and features of the invention will be set forth in part in the description which follows and will become apparent to those having ordinary skill in the art upon examination of the following. These and other advantages of the invention may be realized and attained by the structure particularly pointed out in the written description and claims hereof as well as the appended drawings.

To achieve these and other advantages and in accordance with the invention, as embodied and broadly described herein, a method of fabricating a CMOS image sensor according to the present invention includes the steps of sequentially stacking a metal layer and a nitride layer over a semiconductor substrate having an active area and a pad area; forming a metal pad on the pad area by selectively patterning the nitride layer and the metal layer; forming a protecting layer over the semiconductor substrate including the metal pad; forming a pad opening over the metal pad by selectively removing the protecting layer until a surface of the nitride layer is exposed; forming a color filter layer over the active area of the semiconductor substrate; forming a microlens over the color filter layer; and selectively removing the nitride layer exposed via the pad opening.

In another aspect of the present invention, a method of fabricating a CMOS image sensor includes the steps of sequentially stacking a metal layer and a nitride layer over a semiconductor substrate having an active area and a pad area; forming a metal pad on the pad area by selectively patterning the nitride layer and the metal layer; forming a protecting layer over the semiconductor substrate including the metal pad; forming a pad opening over the metal pad by selectively removing the protecting layer until a surface of the nitride layer is exposed, forming a color filter layer over the active area of the semiconductor substrate; selectively removing the nitride layer exposed via the pad opening; and forming a microlens over the color filter layer.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention illustrate exemplary embodiments of the invention and together with the description serve to explain the principle of the invention. In the drawings:

FIG. 1 is a diagram of an equivalent circuit of a unit pixel of a 3T type CMOS image sensor including three transistors;

FIG. 2 is a layout of the unit pixel of the CMOS image sensor shown in FIG. 1;

FIGS. 3A to 3E are cross-sectional diagrams illustrating a CMOS image sensor fabricated according to a conventional method; and

FIGS. 4A to 4F are cross-sectional diagrams illustrating a CMOS image sensor fabricated in accordance with one exemplary embodiment of the present invention.

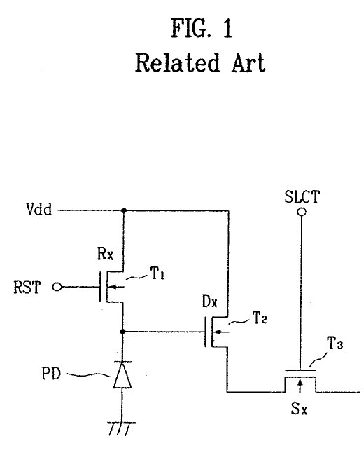

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

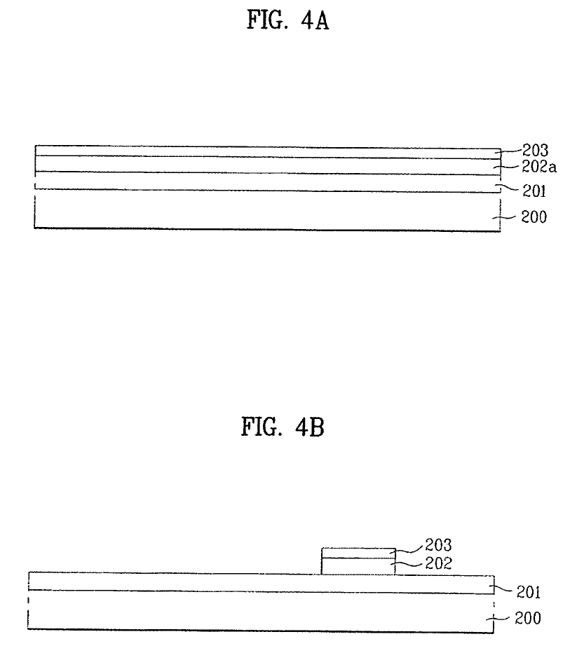

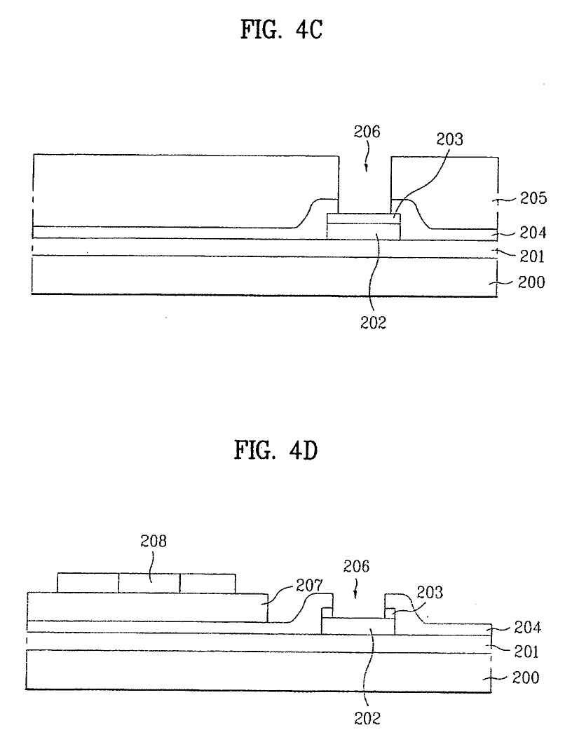

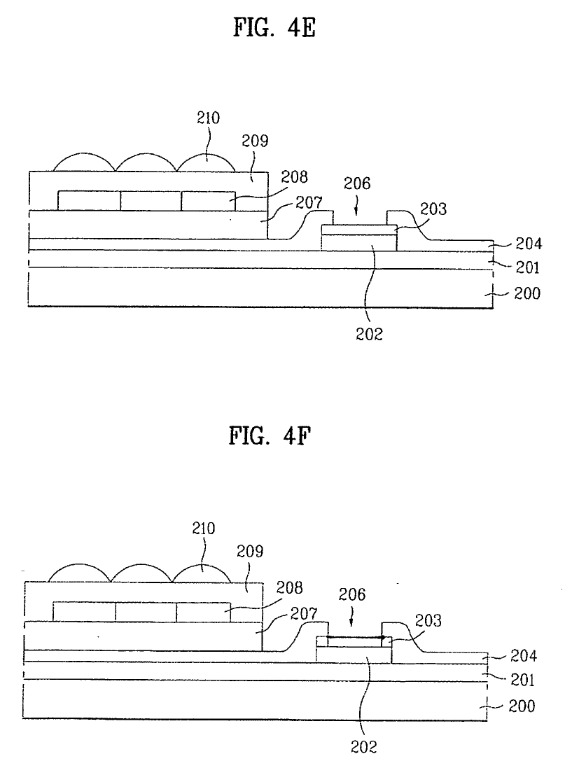

FIGS. 4A to 4F are cross-sectional diagrams illustrating a CMOS image sensor fabricated in accordance with one exemplary embodiment of the present invention.

Referring to FIG. 4A, an insulating layer 201 (e.g., oxide layer), such as a gate insulating layer, an insulating interlayer or other layer, is formed on a semiconductor substrate 201 having an active area and a pad area.

A metal layer 202a for a metal pad is deposited on the insulating layer 201. A nitride layer 203 is formed on the metal layer 202a. The nitride layer 203 can be 100-1,000 Å thick. If the nitride layer 203 is formed too thin, the nitride layer 203 may be removed as a limitation of an etch selection ratio for forming a pad opening. If the nitride layer 203 is formed too thick, excessive etch may be needed to affect the shape of a microlens.

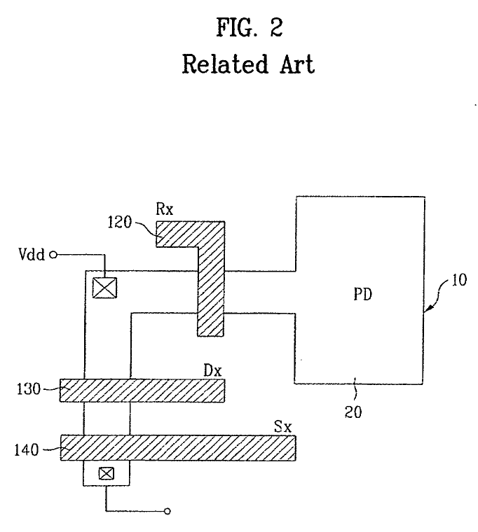

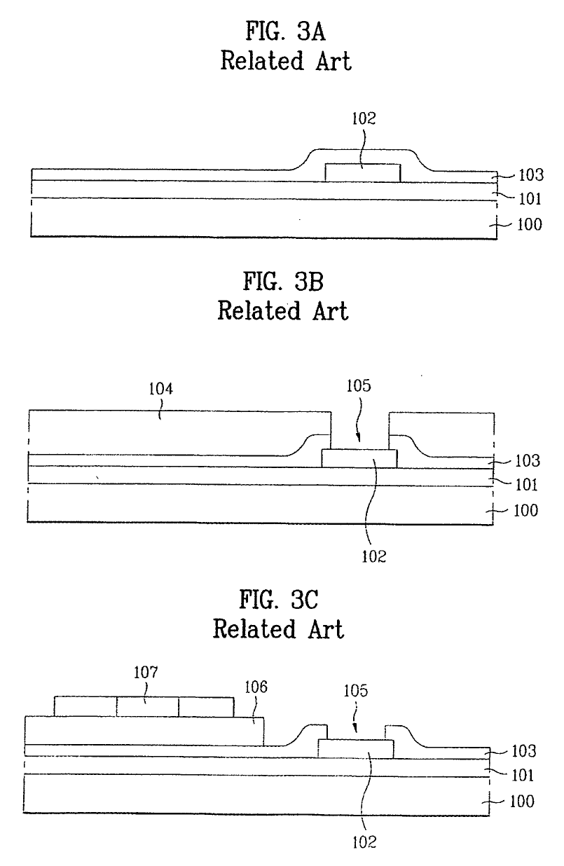

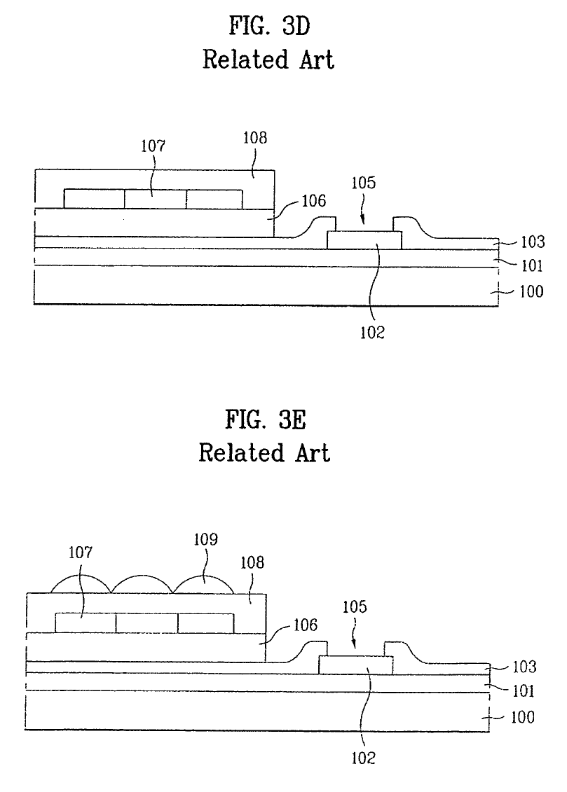

The metal layer 202a can be formed with the same material of the gate electrodes 120, 130 and 140 described with respect to FIG. 2. Alternatively, the metal layer 202a can be formed of a material different from that of the gate electrodes 120, 130 and 140 via a separate contact. The metal layer 202a can be formed with a metal material such as Al, Cu or another similar metal.

For convenience of explanation, Al is discussed as an example in the following description.

Referring to FIG. 4B, the nitride layer 203 and the metal layer 202a are selectively patterned by photolithography to form a metal pad 202 on the pad area of the semiconductor substrate 200. The nitride layer 203 remains on the metal pad 202.

Referring to FIG. 4C, a protecting layer 204 is formed over the semiconductor substrate 200, including the metal pad 202. The protecting layer 204 can be an oxide layer, a nitride layer or other layer.

A photoresist layer 205 is coated on the protecting layer 204 and is then patterned by exposure and development to expose a portion of the protecting layer 204 over the metal pad 202.

A pad opening 206 is formed over the metal pad 202 by selectively etching the protecting layer 204 using the patterned photoresist player 205 as a mask. The nitride layer 203 can play a role as an etch-stop layer in the opening the metal pad 202 using an etch selectivity between the nitride layer 203 and the protecting layer 204. Hence, the nitride layer 203 remains on the metal pad 202 when etching the protecting layer 204. In other words, in this step, the pad opening 206 is formed to open a surface of the nitride layer 203.

Referring to FIG. 4D, the patterned photoresist layer 205 is removed.

A first planarizing layer 207 is formed by depositing a silicon nitride layer or a silicon oxide nitride layer over the semiconductor substrate 200, including the pad opening 206.

The first planarizing layer 207 is then selectively etched by photolithography to only remain on the active area of the semiconductor substrate 200.

Subsequently, color filter layers 208 are formed on the first planarizing layer 207 corresponding to photodiode areas (not shown), respectively.

In this case, each of the color filter layers 208 is formed by coating a corresponding color (e.g., R, G, B) resist and by performing a photo process using a separate mask.

Referring to FIG. 4E, a second planarizing layer 209 is formed over the semiconductor substrate 200, including the color filter layers 208. The second planarizing layer 209 is selectively etched by photolithography to only remain on the active area of the semiconductor substrate 200.

A microlens resist layer is coated on the second planarizing layer 209. A microlens pattern is formed by exposing and developing the microlens resist layer. Reflow is carried out on the microlens pattern at a prescribed temperature to form a hemispherical microlens 210 on the second planarizing layer 209 to correspond to each of the color filter layers 208.

Referring to FIG. 4F, the nitride layer 203 exposed via the pad opening 206 is selectively etched away by blanket etch to expose the metal pad 202.

A contact resistance is tested by performing a probe test on the metal pad 202 of the CMOS image sensor. If the probe test is successful, the metal pad 202 is electrically connected to an external drive circuit.

In the above-explained exemplary embodiment of the present invention, the nitride layer 230 is removed via the pad opening 206 after the microlens 210 has been formed. Alternatively, the nitride layer 230 can be removed by blanket etch via the pad opening 206 prior to forming the microlens 210, but after the second planarizing layer 209 has been formed.

The nitride layer is deposited on the metal layer for the metal pad. The etch for forming the pad opening is stopped using the etch selectivity between the nitride layer and the oxide layer. Hence, the metal pad is not opened at this point. As such, the metal can be prevented from contacting with the alkali developing solution utilized in performing the color filter process, the planarizing process and/or the microlens process. Therefore, the present invention can enhance performance and output of the image sensor.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. A method of fabricating a CMOS image sensor, comprising the steps of:
sequentially stacking a metal layer and a nitride layer over a semiconductor substrate having an active area and a pad area;
forming a metal pad on the pad area by selectively patterning the nitride layer and the metal layer;
forming a protecting layer over the semiconductor substrate including the metal pad;
forming a pad opening over the metal pad by selectively removing the protecting layer until a surface of the nitride layer is exposed;
forming a color filter layer over the active area of the semiconductor substrate;
forming a microlens over the color filter layer; and
selectively removing the nitride layer exposed via the pad opening.

2. The method of claim 1, wherein, in the pad opening forming step, the surface of the nitride layer is used as an etch stop layer using an etch selectivity between the nitride layer and the protecting layer.

3. The method of claim 1, wherein the nitride layer exposed via the pad opening is removed by blanket etch.

4. The method of claim 1, wherein the nitride layer is 100-1,000 Å thick.

5. The method of claim 1, wherein the metal pad is formed of Al.

6. The method of claim 1, further comprising the step of forming an insulating layer on the semiconductor substrate prior to forming the metal layer over the semiconductor substrate.

7. The method of claim 1, further comprising the step of forming a first planarizing layer over the active area of the semiconductor substrate prior to forming the color filter layer over the active area of the semiconductor substrate.

8. The method of claim 1, further comprising the step of forming a second planarizing layer on the color filter layer prior to forming the microlens over the color filter layer.

9. A method of fabricating a CMOS image sensor, comprising the steps of:
sequentially stacking a metal layer and a nitride layer over a semiconductor substrate divided into an active area and a pad area;
forming a metal pad on the pad area by selectively patterning the nitride layer and the metal layer;
forming a protecting layer over the semiconductor substrate including the metal pad;
forming a pad opening over the metal pad by selectively removing the protecting layer until a surface of the nitride layer is exposed;
forming a color filter layer over the active area of the semiconductor substrate;
selectively removing the nitride layer exposed via the pad opening; and
forming a microlens over the color filter layer.

10. The method of claim 9, wherein, in the pad opening forming step, the surface of the nitride layer is used as an etch stop layer using an etch selectivity between the nitride layer and the protecting layer.

11. The method of claim 9, wherein the nitride layer exposed via the pad opening is removed by blanket etch.

12. The method of claim 9, wherein the nitride layer is 100-1,000 Å thick.

13. The method of claim 9, wherein the metal pad is formed of Al.

14. The method of claim 9, further comprising the step of forming an insulating layer on the semiconductor substrate prior to forming the metal layer over the semiconductor substrate.

15. The method of claim 9, further comprising the step of forming a first planarizing layer over the active area of the semiconductor substrate prior to forming the color filter layer over the active area of the semiconductor substrate.

16. The method of claim 9, further comprising the step of forming a second planarizing layer on the color filter layer prior to forming the microlens over the color filter layer.
